(19) United States
(12) Patent Application Publication
(10) Pub. No.: US 2013/0160703 A1
(43) Pub. Date: Jun. 27, 2013

(54) CARBON CRUCIBLE

(71) Applicants: Osamu Okada, Mitoyo-shi (JP); Yoshiaki Hirose, Mitoyo-shi (JP); Tetsuya Yuki, Mitoyo-shi (JP); Hiromitsu Sugawa, Osaka-shi (JP)

(72) Inventors: Osamu Okada, Mitoyo-shi (JP); Yoshiaki Hirose, Mitoyo-shi (JP); Tetsuya Yuki, Mitoyo-shi (JP); Hiromitsu Sugawa, Osaka-shi (JP)

(73) Assignee: TOYO TANSO CO., LTD., Osaka-shi, Osaka (JP)

(21) Appl. No.: 13/820,796

(22) PCT Filed: Aug. 26, 2011
(86) PCT No.: PCT/JP2011/069304

§ 371 Date: Mar. 5, 2013

(30) Foreign Application Priority Data
Sep. 6, 2010 (JP) 2010-199174
Sep. 6, 2010 (JP) 2010-199233

(51) Int. Cl. C30B 15/10

(52) U.S. Cl. CPC C30B 15/10
USPC 117/208

(57) ABSTRACT

A carbon crucible prevents leakage of SiO gas from a boundary portion between a straight trunk portion and a tray portion and prevents SiC formation from quickly developing. A carbon crucible (5) for retaining a quartz crucible (4) used in a metal single crystal pulling apparatus for silicon or the like has a straight trunk portion (9) and a tray portion (10) that are divided from each other. A graphite sheet (11) is disposed between the quartz crucible (4) and the carbon crucible (5) so as to cover at least a boundary portion (A) of an inner surface of the carbon crucible (5) between the straight trunk portion (9) and the tray portion (10). The graphite sheet (11) is an expanded graphite sheet.

### TECHNICAL FIELD

The present invention relates to a carbon crucible for retaining a quartz crucible used in a metal single crystal pulling apparatus for silicon or the like.

### BACKGROUND ART

1. First Related Art

A crucible used for the Czochralski process (hereinafter referred to as the “CZ process”) has a double structure including a quartz crucible for melting silicon and a graphite crucible for accommodating the quartz crucible. In recent years, large-sized single crystals tend to have been produced in order to obtain silicon single crystals at high yield rates. Correspondingly, large-sized graphite crucibles have become necessary. However, as the capacity of the graphite crucible increases, the heat warpage resulting from the difference in thermal expansion rate between the quartz crucible and the graphite crucible accordingly increases. Consequently, stress concentration occurs in the straight trunk portion, especially in the upper edge portion thereof and in the curved surface portion (hereinafter may be referred to as a “curved portion”) that is connected from the bottom portion to the straight trunk portion, so that cracks of the graphite crucible are likely to occur. In order to resolve this problem, some proposals have been made, such as a graphite crucible in which the straight trunk portion and the tray portion are separated (see Patent Documents 1 to 4 indicated below) and a composite crucible in which the straight trunk portion uses a carbon fiber-reinforced carbon composite material (C/C material) and the tray portion uses a graphite material (see Patent Document 5 indicated below).

2. Second Related Art

In addition, a silicon single crystal pulling apparatus conventionally uses a crucible apparatus that comprises a quartz crucible for accommodating silicon melt and a graphite crucible for retaining the quartz crucible. In such a crucible apparatus, defects such as cracks may arise in the graphite crucible in a cooling process due to the difference in thermal expansion coefficient between the graphite crucible and the quartz crucible.

In view of the problem, in recent years, a crucible retaining member (corresponding to a carbon crucible) made of a carbon fiber-reinforced carbon composite material (C/C material) and composed of a net-shaped material woven in a net shape has been proposed in place of the graphite crucible (see Patent Documents 6 and 7 indicated below). However, in the case of using the crucible retaining member composed of the net-shaped material, the quartz crucible may soften and encroach into the gap portions of the mesh if the mesh size of the net-shaped material is small, and consequently, the quartz crucible may become difficult to remove. As a measure to resolve such a problem, Patent Document 7 discloses a configuration in which a sheet, such as an expanded graphite sheet, is interposed between the net-shaped material and the quartz crucible (see paragraph 0021 of Patent Document 7).

### Citation List

### Patent Literature

[Patent Document 1] Japanese Utility Model No. 3012299

[Patent Document 2] Japanese Published Unexamined Patent Application No. H07(1995)-25694 A

[Patent Document 3] Japanese Published Unexamined Patent Application No. H09(1997)-263482 A

[Patent Document 4] Japanese Published Unexamined Patent Application No. 2000-247781 A

[Patent Document 5] Japanese Published Unexamined Patent Application No. S63(1988)-7174 A

[Patent Document 6] Japanese Published Unexamined Patent Application No. H02(1990)-116696 A

[Patent Reference 7] Japanese Published Unexamined Patent Application No. 2009-203093 A

### SUMMARY OF INVENTION

### Technical Problem

(Technical Problem Related to the First Related Art)

During the time in which a silicon single crystal is grown by a silicon single crystal pulling apparatus, SiO is vaporized from silicon melt. This SiO gas is discharged from the chamber by a vacuum pump together with Ar gas introduced into the chamber, but at the same time, it gets into the gap between the graphite crucible and the quartz crucible. Consequently, the SiO reacts with the carbon in the graphite crucible, encouraging the graphite crucible inner surface to turn into SiC.

Furthermore, this layer of the graphite crucible that has been turned into SiC and SiO₂ (quartz crucible) react with each other, so SiO and CO gas are generated while consuming the SiC. Thereby, wall thickness reduction (consumption) of the graphite crucible develops. In particular, when the graphite crucible is the one that is divided, inflow and outflow of the gas occurs at the boundary portion between the straight trunk portion and the tray portion, and consequently, the wall thickness reduction develops considerably.

The foregoing reactions are summarized below.

(1) Reaction between the quartz crucible and Si

SiO₂+Si→2SiO

(2) Reaction between the quartz crucible and the graphite crucible

SiO₂+C→SiO+CO

SiO₂+C→SiC+O₂

(3) Reaction between the generated SiO gas and the crucible

2SiO+2C→2SiC+O₂

(4) Reaction (oxidation) with the generated O₂ gas and the CO gas

O₂+C→CO₂

O₂+2C→2CO, 2CO+C→2C (soot)+CO₂

When the graphite crucible in which the wall thickness reduction has developed considerably is used, the quartz crucible is locally depressed into the portion of the graphite crucible in which the wall thickness has been reduced. When the operating hour becomes long, there is a risk that cracks develop in the depressed portion and the silicon melt leaks through the cracks and builds up inside the furnace. For this reason, the graphite crucible needs to be replaced with a new one when the amount of the wall thickness reduction exceeds a certain amount.

Thus, a problem with the crucible that is divided has been that SiO gas leaks from the boundary portion between the straight trunk portion and the tray portion and the formation of SiC develops at an early stage.

However, no effective measure to solve the problem of the SiC formation from the boundary portion between the straight trunk portion and the tray portion is disclosed in Patent Documents 1 to 5 indicated above. Accordingly, there has been a need for a carbon crucible that is configured to prevent the leakage of SiO gas from the boundary portion between the straight trunk portion and the tray portion.

(Technical Problem Related to the Second Related Art)

In the case of using the crucible retaining member composed of the net-shaped material, another problem arises that the stability of the metal crystal that is the product may be adversely affected, in addition to the above-described problem that the quartz crucible softens and gets into the gap portions of the mesh size. For example, when the quartz crucible softens, bumps and dents are formed in the inner surface of the quartz crucible because of the protrusion of the quartz crucible from the inner surface of the net-shaped material. When the crucible is rotated in one direction under such a condition, the melt flows into the dents, causing turbulence in the flow of the melt. This hinders the crystal growth of the metal single crystal, leading to degradation of the quality. However, Patent Document 7 indicated above does not disclose any solution relating to such stability of the quality of the metal crystal.

Accordingly, it has been desired to provide a carbon crucible that can prevent the degradation of the quality of the metal crystal, which results from the turbulence of the flow of the melt.

In view of the foregoing circumstances, it is an object of the present invention to provide a carbon crucible that prevents leakage of SiO gas from the boundary portion between the straight trunk portion and the tray portion and prevents SiC formation from quickly developing.

In view of the foregoing circumstances, it is another object of the present invention to provide a carbon crucible that achieves, in particular, prevention of degradation of the quality of the metal crystal that results from turbulence of the flow of the melt, in addition to improvement in the net-shaped material, easy detachment from the quartz crucible, and prevention of encroachment of the quartz crucible into the net-shaped material.

### Solution to Problem

In order to accomplish the foregoing objects, the present invention provides a carbon crucible having a straight trunk portion and a tray portion divided from each other, wherein a graphite sheet is disposed so as to cover at least a boundary portion of an inner surface of the carbon crucible between the straight trunk portion and the tray portion.

With the above-described configuration, the boundary portion between the straight trunk portion and the tray portion is covered by the graphite sheet, and therefore, it is made possible to prevent leakage of SiO gas from the boundary portion and to prevent the carbon crucible from turning into SiC at an early stage.

In the present invention, it is preferable that the graphite sheet be an expanded graphite sheet.

In the above-described configuration, the expanded graphite sheet has high cushioning capability. Therefore, when the graphite sheet is sandwiched, the graphite sheet is compressed between the quartz crucible and the boundary portion without forming any gap. Therefore, leakage of SiO gas can be prevented more effectively.

In the present invention, it is preferable that the graphite sheet have an ash content of 100 ppm or less.

The above-described configuration makes it possible to reduce the metallic impurities originating from the graphite sheet and lead to stabilization of the quality of, in particular, metal single crystals for semiconductor applications.

In the present invention, it is preferable that the straight trunk portion be made of a carbon fiber-reinforced carbon composite material (C/C material), and the graphite sheet be disposed so as to cover an entire inner surface of the straight trunk portion in addition to the boundary portion.

With the above-described configuration, the durability of the carbon crucible can be remarkably improved by covering the boundary portion and the straight trunk portion that is porous and likely to cause “corrosion” at the same time.

In the present invention, it is preferable that the straight trunk portion comprise a plurality of graphite divided pieces divided from each other, and the graphite sheet be disposed so as to cover an entire inner surface of the straight trunk portion in addition to the boundary portion.

When the straight trunk portion that is a separate part from the tray portion is formed of graphite, it is essential to divide the straight trunk portion because cracks tend to form easily in the straight trunk portion due to temperature changes. However, when the straight trunk portion is divided, there is a risk that leakage of SiO gas may be caused at the divided part. In view of this, the failures resulting from the leakage of SiO gas can be prevented by covering the divided part and the boundary portion by the graphite sheet.

In the present invention, it is preferable that the tray portion comprise a bottom portion and a curved surface-shaped portion (curved portion) connected from the bottom portion to the straight trunk portion, and the graphite sheet be disposed so as to unitarily the entire inner surface of the straight trunk portion and the curved surface-shaped portion, in addition to the boundary portion.

With the above-described configuration, the straight trunk portion, the boundary portion, and the curved portion of the tray portion, which is consumed most, is unitarily covered, so that the leakage of SiO gas can be reliably prevented and the local SiC formation can be inhibited.

In the present invention, it is preferable that the graphite sheet be disposed so as to unitarily cover the inner surface of the carbon crucible.

With the above-described configuration, since the inner surface is covered by a one-piece sheet, gaps are unlikely to be formed. As a result, SiO gas is prevented from leaking, and the carbon crucible and the quartz crucible are prevented from, for example, making contact with each other.

In the present invention, it is preferable that the graphite sheet comprise a flat circular shaped sheet for covering the inner surface of the tray portion and a tubular sheet for covering the inner surface of the straight trunk portion, the flat circular shaped sheet and the tubular sheet being combined with each other, and both of the sheets be overlapped at the boundary portion.

With the above-described configuration, the sheets can be processed easily even when the tray portion and the straight trunk portion are made of separate parts and especially when the vertical size of the straight trunk portion is large (when the capacity of the melt is large in solar batteries). Moreover, since both sheets are overlapped, the quartz crucible and the tray portion are prevented from making contact with each other.

In the present invention, it is preferable that the tray portion comprise a plurality of graphite divided pieces divided from each other, and the graphite sheet comprise a tray sheet portion for covering a butt joint portion of the divided pieces and a vicinity thereof, and a boundary sheet portion for covering the boundary portion.

With the above-described configuration, leakage of SiO gas can be prevented with a small amount of the sheet, and sufficient effects can be obtained for inhibiting local SiC formation.

In the present invention, it is preferable that the graphite sheet comprises a plurality of graphite sheets stack on each other.

With the above-described configuration, the surface level difference between the tray portion and the straight trunk portion can be easily compensated. Moreover, gaps are inhibited from forming in the vicinity of the surface level difference by increasing the cushioning capability, so that leakage of SiO gas from the gaps can be prevented.

In the present invention, it is preferable that the graphite sheet have a thickness of from 0.2 mm to 1.0 mm and a bulk density of from 0.7 g/cm³ to 1.3 g/cm³.

With the above-described configuration, the graphite sheet is provided with a sheet thickness and a bulk density that are necessary for lining, so that it can offer high performance.

It is preferable that the straight trunk portion comprise a net-shaped material made of a carbon fiber-reinforced carbon composite material and woven in a net shape, and the graphite sheet be disposed so as to cover an entire inner surface of the straight trunk portion in addition to the boundary portion (this is hereinafter referred to as the present invention provided with the net-shaped straight trunk portion).

With the above-described configuration, the graphite sheet prevents the straight trunk portion comprising a net-shaped material (hereinafter referred to as the net-shaped straight trunk portion) from making direct contact with the quartz crucible. Therefore, the deterioration of the net-shaped straight trunk portion resulting from the reaction with the quartz crucible does not occur easily, so the lifetime improves. In addition, it is possible to achieve easy detachment from the quartz crucible, prevention of encroachment of the quartz crucible into the net-shaped straight trunk portion, and the like.

In addition, since the entire inner surface of the net-shaped straight trunk portion is covered, all the mesh holes are closed. As a result, the formation of the bumps and dents in the inner surface of the quartz crucible, which results from protrusion of the quartz crucible from the inner surface of the net-shaped straight trunk portion caused by the softening of the quartz crucible, is alleviated, and the flow of the melt in the quartz crucible that is rotated in one direction is stabilized. Therefore, the metal single crystal obtained by pulling can be one that has less defects and stable quality.

Moreover, the area of the quartz crucible that is exposed inside the furnace becomes remarkably small, so it is possible to reduce the risk that the SiO gas generated from the quartz crucible may cause adverse effects on the internal material of the furnace.

Furthermore, since the graphite sheet covers the boundary portion between the tray portion and the net-shaped straight trunk portion as described above, leakage of the SiO gas from the boundary portion can be prevented, and the local SiC formation can be inhibited. Moreover, misalignment of the net-shaped straight trunk portion from the tray portion can also be inhibited.

In the present invention provided with the net-shaped straight trunk portion, it is preferable that the graphite sheet be an expanded graphite sheet.

By applying the invention to the net-shaped material, which has a small area by which the quartz crucible is retained, the risk of breakage of the quartz crucible can be reduced at the time of installing. More specifically, since the expanded graphite sheet has high cushioning capability, the quartz crucible can be retained resiliently because of the cushioning capability even when the area in the net-shaped material by which the quartz crucible is retained is small. As a result, the quartz crucible is prevented from breaking at the time of installing the quartz crucible.

In the present invention provided with the net-shaped straight trunk portion, it is preferable that the graphite sheet have an ash content of 100 ppm or less.

Such a configuration makes it possible to reduce the metallic impurities originating from the graphite sheet and lead to stabilization of the quality of, in particular, metal single crystals for semiconductor applications. In addition, the highly purified sheet has high hardness and it can increase the effect of inhibiting the softened quartz crucible from protruding outside. In particular, when the net-shaped straight trunk portion is used, metallic impurities are released from the graphite sheet at a greater rate. For this reason, the above-described configuration can become effective particularly in the applications in which metallic impurities should be avoided.

In the present invention provided with the net-shaped straight trunk portion, it is preferable that the tray portion comprise a bottom portion and a curved surface-shaped portion (curved portion) connected from the bottom portion to the net-shaped straight trunk portion, and the graphite sheet be disposed so as to unitarily cover the entire inner surface of the net-shaped straight trunk portion and the curved surface-shaped portion (curved portion) of the tray portion.

In the above-described configuration, the curved portion, which is consumed most among the straight trunk portion, the boundary portion, and the tray portion, is unitarily covered. As a result, the local SiC formation can be inhibited.

In the present invention provided with the net-shaped straight trunk portion, it is preferable that the graphite sheet be disposed so as to unitarily cover the entire inner surface of the net-shaped straight trunk portion and the tray portion.

With the above-described configuration, since the inner surface is covered by a one-piece sheet, gaps resulting from misplacement of the sheets or the like are unlikely to be formed. As a result, SiO gas is prevented from leaking, and the net-shaped straight trunk portion and the quartz crucible are prevented from, for example, making contact with each other.

In the present invention provided with the net-shaped straight trunk portion, it is preferable that the graphite sheet comprise a flat circular shaped sheet for covering the inner surface of the tray portion and a tubular sheet for covering the inner surface of the straight trunk portion, the flat circular shaped sheet and the tubular sheet being combined with each other, and both of the sheets be overlapped at the boundary portion.

With the above-described configuration, the sheet can be processed easily for covering the necessary portions without any gap even when the tray portion and the net-shaped straight trunk portion are made of separate parts and especially when the vertical size of the net-shaped straight trunk portion is large. Moreover, since both sheets are overlapped so as to eliminate gaps therebetween, the quartz crucible and the tray portion are prevented from making contact with each other.

In the above-described present invention having the straight trunk portion, it is preferable that the graphite sheet have a thickness of from 0.2 mm to 1.0 mm and a bulk density of from 0.7 g/cm³ to 1.3 g/cm³.

With the above-described configuration, the graphite sheet is provided with a sheet thickness and a bulk density that are necessary for lining, so that it can offer high performance.

### Advantageous Effects of Invention

The present invention makes it possible to prevent leakage of SiO gas from the boundary portion and to prevent the carbon crucible from turning into SiC at an early stage by covering the boundary portion between the straight trunk portion and the tray portion by the graphite sheet.

### BRIEF DESCRIPTION OF DRAWINGS

FIG. 1 is a cross-sectional view illustrating a primary portion of a silicon single crystal pulling apparatus according to Embodiment 1-1.

FIG. 2 is an enlarged cross-sectional view of a crucible used in the silicon single crystal pulling apparatus of FIG. 1.

FIG. 3 is a view illustrating another arrangement of the graphite sheet.

FIG. 4 is a view illustrating another arrangement of the graphite sheet.

FIG. 5 is a view illustrating the shape of the graphite sheet used for the arrangement shown in FIG. 4.

FIG. 6 is a view illustrating another arrangement of the graphite sheet.

FIG. 7 is a view illustrating the shape of the graphite sheet used for the arrangement shown in FIG. 6.

FIG. 8 is a view illustrating the shape of a flat circular shaped sheet 11a.

FIG. 9 is a plan view illustrating a tray portion 10 used in Embodiment 1-3.

FIG. 10 is a view illustrating the shape of the graphite sheet used in Embodiment 1-3.

FIG. 11 is a cross-sectional view illustrating a primary portion of a silicon single crystal pulling apparatus according to Embodiment 2.

FIG. 12 is an enlarged cross-sectional view of a crucible used in the silicon single crystal pulling apparatus of FIG. 11.

FIG. 13 is a view illustrating another structure of a net-shaped material.

FIG. 14 is a view for illustrating the turbulence of the melt in the case where irregular portions are formed in a quartz crucible inner surface.

FIG. 15 is a view illustrating another arrangement of the graphite sheet.

FIG. 16 is a view illustrating another arrangement of the graphite sheet.

FIG. 17 is a view illustrating the shape of the graphite sheet used for the arrangement shown in FIG. 16.

FIG. 18 is a view illustrating another arrangement of the graphite sheet.

FIG. 19 is a view illustrating the shape of the graphite sheet used for the arrangement shown in FIG. 18.

FIG. 20 is a view illustrating the shape of a flat circular shaped sheet 11b.

### DESCRIPTION OF EMBODIMENTS

Hereinbelow, the present invention will be described based on the preferred embodiments. It should be noted that the present invention is not limited to the following embodiments.

### Embodiment 1

### Embodiment 1-1

(Configuration of Metal Single Crystal Pulling Apparatus)

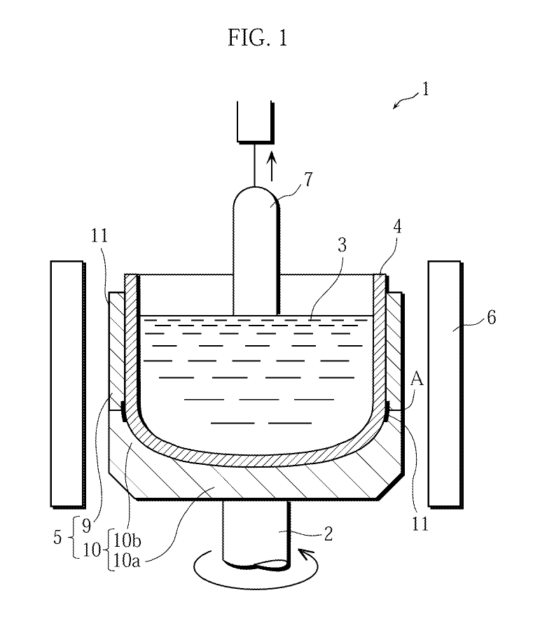

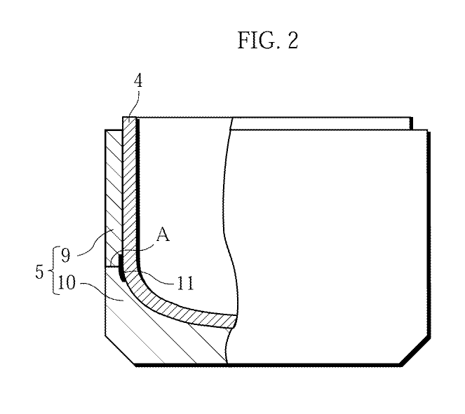

FIG. 1 is a cross-sectional view illustrating a primary portion of a silicon single crystal pulling apparatus according to Embodiment 1-1, and FIG. 2 is an enlarged cross-sectional view of a crucible. In FIG. 1, reference numeral 1 denotes a single crystal pulling apparatus, reference numeral 2 denotes a shaft, reference numeral 4 denotes a quartz crucible for accommodating silicon melt 3, and reference numeral 5 denotes a carbon crucible for retaining the quartz crucible 4. A heater 6 is disposed around the outer periphery of the carbon crucible 5. The silicon melt 3 is heated by the heater 6 through the carbon crucible 5 and the quartz crucible 4, and while pulling up an ingot 7, a silicon single crystal is produced.

The carbon crucible 5 has a substantially circular tubular straight trunk portion 9 and a tray portion 10, and the straight trunk portion 9 and the tray portion 10 are divided from each other. The straight trunk portion 9 is mounted on the tray portion 10, and respective butt joint surfaces of the straight trunk portion 9 and the tray portion 10 are fitted and firmly affixed to each other. A graphite sheet 11 is disposed between the quartz crucible 4 and the carbon crucible 5 so as to cover at least a boundary portion A of the inner surface of the carbon crucible 5 between the straight trunk portion 9 and the tray portion 10.

The straight trunk portion 9 is made of a carbon fiber-reinforced carbon composite material (C/C material), and the tray portion 10 is made of graphite. The tray portion 10 comprises a bottom portion 10a and a curved surface-shaped portion (hereinafter referred to as the “curved portion”) 10b connected from the bottom portion 10a to the straight trunk portion 9.

It is preferable that the graphite sheet 11 be an expanded graphite sheet. The reason is as follows. The expanded graphite sheet has high cushioning capability. Therefore, when the graphite sheet 11 is sandwiched, the graphite sheet 11 is compressed between the quartz crucible 4 and the boundary portion A without forming any gap. As a result, leakage of SiO gas can be prevented more effectively.

It is preferable that the expanded graphite sheet used as the graphite sheet 11 have a thickness of from about 0.2 mm to about 1.0 mm and a bulk density of from about 0.7 g/cm³ to about 1.3 g/cm³.

It is also preferable that the graphite sheet 11 be one with high purity that has an ash content of 100 ppm or less, more preferably ash content 50 ppm or less. The reason is that it makes possible to reduce the metallic impurities originating from the graphite sheet 11 and lead to stabilization of the quality of, in particular, metal single crystals for semiconductor applications.

It should be noted that the straight trunk portion 9 and the tray portion 10 may be coated or impregnated with pyrocarbon or the like.

(Arrangements of the Graphite Sheet)

There exist various embodiments of arrangement of the graphite sheet 11 as described below.

(1) An embodiment in which the graphite sheet 11 is disposed so as to cover the boundary portion A of the inner surface of the carbon crucible 5 between the straight trunk portion 9 and the tray portion 10 (see FIG. 2).

When the graphite sheet 11 is disposed so as to cover the boundary portion A between the straight trunk portion 9 and the tray portion 10, leakage of SiO gas from the boundary portion A, which is especially problematic in the crucible in which the straight trunk portion 9 and the tray portion 10 are divided from each other, can be prevented, and the carbon crucible can be prevented from quickly turning into SiC.

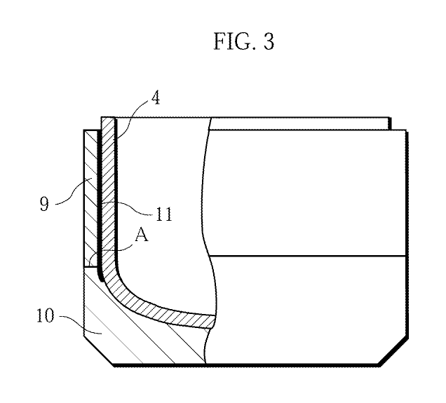

(2) An embodiment in which the graphite sheet 11 is disposed so as to cover the entire inner surface of the straight trunk portion 9, in addition to the boundary portion A (see FIG. 3).

When the graphite sheet 11 is disposed according to the just-described embodiment of arrangement, the durability of the carbon crucible 5 can be remarkably improved by covering the boundary portion A and the straight trunk portion 9 that is porous and likely to cause “corrosion” at the same time.

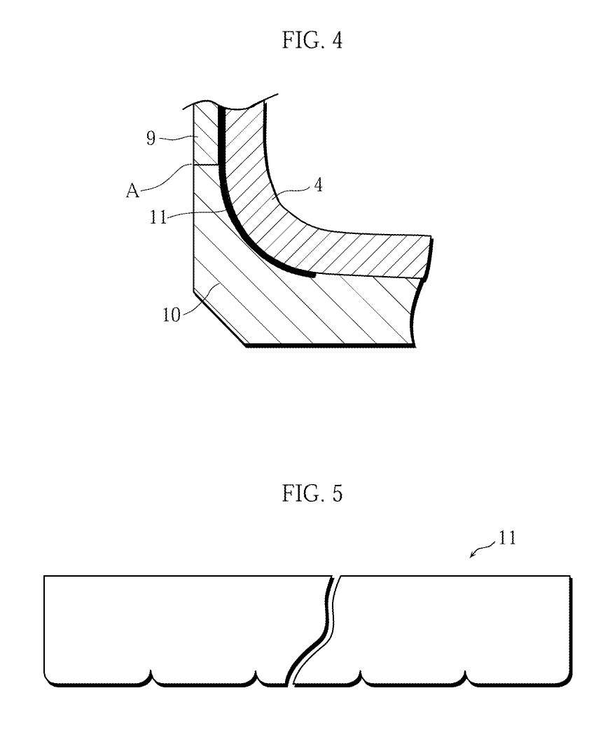

(3) An embodiment in which the graphite sheet 11 is disposed so as to unitarily cover the entire inner surface of the straight trunk portion 9 and also the curved portion 10b of the tray portion 10 (see FIG. 4).

When the graphite sheet 11 is disposed according to the just-described arrangement embodiment, the straight trunk portion 9, the boundary portion A, and the curved portion 10b of the tray portion 10, which is consumed most, is unitarily covered, so that leakage of SiO gas can be reliably prevented and the local SiC formation can be inhibited.

The graphite sheet 11 used in this case may have, for example, a shape in which the upper portion thereof follows the straight trunk portion 9 and the lower end and vicinity thereof follow the curved portion 10b of the tray portion 10, as illustrated in FIG. 5.

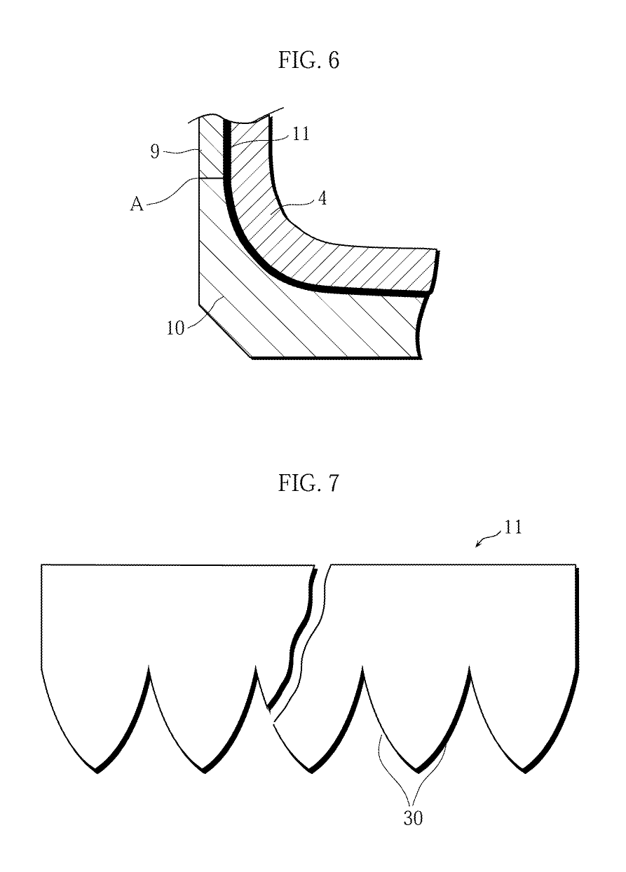

(4) An embodiment in which the graphite sheet 11 is disposed so as to unitarily cover the inner surface of the carbon crucible 5 (see FIG. 6).

When the graphite sheet 11 is disposed according to the just-described arrangement embodiment, gaps are unlikely to be formed since the inner surface is covered by the one-piece sheet. As a result, SiO gas is prevented from leaking, and the carbon crucible 5 and the quartz crucible 4 are prevented from, for example, making contact with each other.

A sheet having the shape shown in FIG. 7, for example, is used as the graphite sheet 11 in this embodiment. Specifically, by forming incisions 30 at the lower end of the sheet 11 so that the sheet can follow the bottom face shape of the crucible 5, the bottom portion of the sheet forms a spherical face. The size of the incision 30 can be determined as appropriate according to the shape of the tray portion 10 of the crucible, particularly according to the curvature of the bottom portion 10a.

(5) An embodiment in which the graphite sheet 11 is disposed so that a flat circular shaped sheet 11a for covering the inner surface of the tray portion 10 and a tubular sheet for covering the inner surface of the straight trunk portion 9 are combined with each other and that both of the sheets are overlapped at the boundary portion.

When the graphite sheet 11 is disposed according to the just-described embodiment, the sheet can be processed easily even when the tray portion 10 and the straight trunk portion 9 are made of separate parts and especially when the vertical size of the straight trunk portion 9 is large (when the capacity of the melt is large in solar batteries). Moreover, since both sheets are overlapped, the quartz crucible 4 and the tray portion 10 are prevented from making contact with each other.

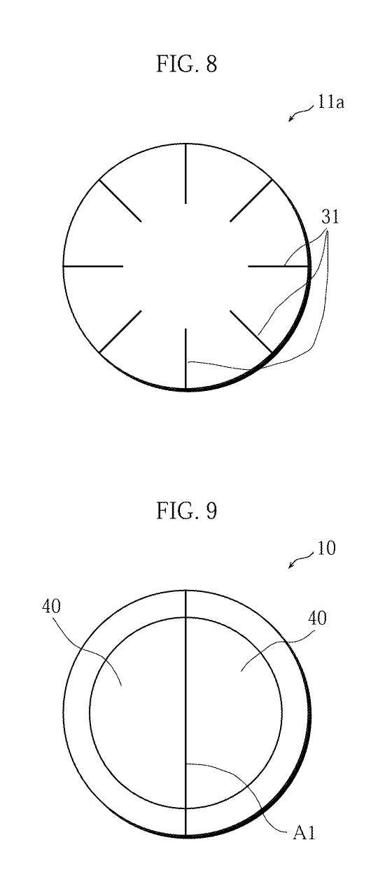

In this embodiment, the flat circular shaped sheet 11a may be, for example, a sheet having the shape shown in FIG. 8, and the tubular sheet may be, for example, a sheet having the shape shown in FIG. 5. With the sheet having the shape shown in FIG. 8, slits 31 provided in the outer periphery of the circular shape allow the peripheral region of the circular shape to be in such a shape as to follow the curved portion 10b, and both sheets overlap with each other at a slightly downward portion of the curved portion 10b by combining it with the sheet as shown in FIG. 5, to thus obtain an arrangement with no gap.

(6) An embodiment in which the graphite sheet 11 comprises a plurality of graphite sheets stacked on each other.

By employing the just-described embodiment, the surface level difference between the tray portion 10 and the straight trunk portion 9 can be easily compensated. Moreover, gaps are inhibited from forming in the vicinity of the surface level difference by increasing the cushioning capability, so that leakage of SiO gas from the gaps can be prevented. More specifically, in the crucible in which the straight trunk portion 9 and the tray portion 10 are divided from each other, a surface level difference may arise between the tray portion 10 and the straight trunk portion 9, and SiO gas may leak from the gaps. In such a case, when the graphite sheet 11 comprises a plurality of sheets stacked on each other, the cushioning capability is increased so that the gaps are prevented from forming in the vicinity of the surface level difference between the tray portion 10 and the straight trunk portion 9. As a result, leakage of SiO gas from the gaps can be prevented.

(Manufacturing Method of the Expanded Graphite Sheet)

The expanded graphite sheet may be manufactured in the following manner. A one-piece expanded graphite sheet is a sheet-like material made from expanded graphite, and a typical example is as follows. First, natural or synthetic graphite flakes, kish graphite, or the like are treated with an oxidizing agent, to form an intercalation compound in the graphite particles. Next, this is heated to a high temperature, or preferably exposed abruptly to a high temperature to expand the material rapidly. This treatment causes the graphite particles to expand in a direction perpendicular to the layer plane due to the gas pressure of the intercalation compound of the graphite particles, so that the volume rapidly expands from about 100 times to 250 times normally. The oxidizing agent used in this case is one that forms an intercalation compound, such as a mixed acid of a sulfuric acid and a nitric acid, and a sulfuric acid to which an oxidizing agent such that a sodium nitrate, a potassium permanganate, or the like is added.

Next, impurities are removed to an ash content of 100 ppm or less, more preferably to an ash content of 50 ppm or less, and the expanded graphite is formed into a sheet shape by compressing or roll-forming, to prepare an expanded graphite sheet.

Next, the expanded graphite sheet manufactured in the just-described manner are cut and split into predetermined dimensions and shapes according to the above-described arrangement embodiments, to prepare the expanded graphite sheet 11 according to the present invention.

### Embodiment 1-2

In this embodiment 1-2, the straight trunk portion 9 comprises a plurality of graphite divided pieces divided from each other, and the graphite sheet 11 is disposed so as to cover the entire inner surface of the straight trunk portion 9. When the straight trunk portion 9 that is a separate part from the tray portion 10 is formed of graphite, it is essential to divide the straight trunk portion 9 because cracks tend to form easily in the straight trunk portion 9 due to temperature changes. However, when the straight trunk portion 9 is divided, there is a risk that leakage of SiO gas may be caused at the divided part. In view of this, the failures resulting from the leakage of SiO gas can be prevented by covering the divided part (i.e., the butt joint portion of the graphite divided pieces) and the boundary portion A by the graphite sheet 11 as in the present embodiment 1-2.

### Embodiment 1-3

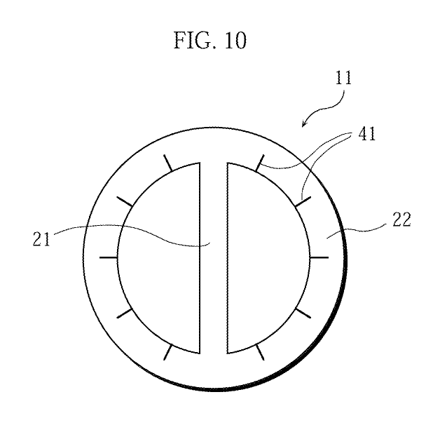

In this embodiment 1-3, as illustrated in FIG. 9, the tray portion 10 comprises graphite divided pieces 40, 40, made by dividing the tray portion into two pieces, and as illustrated in FIG. 10, the graphite sheet 11 comprises a tray sheet portion 21 for covering a divided part A1 (the butt joint portion of the two graphite divided pieces) of the graphite divided pieces 40 and its vicinity, and a boundary sheet portion 22 for covering the boundary portion A, the tray sheet portion 21 and the boundary sheet portion 22 being integrally formed with each other. Note that the boundary sheet portion 22 is provided with slits 41 in the inner side of the outer periphery thereof in order to allow the boundary sheet portion 22 to follow the curved portion.

From the viewpoint of convenience in transportation or the like, the tray portion 10 made of graphite is divided into, for example, two parts or three parts, and the divided portions are butt jointed to form the tray portion 10. However, in such a divided structure, SiO gas passes through the divided parts A1 of the graphite divided pieces 40, and therefore, there is a risk that the divided parts A1 may be selectively turned into SiC. In view of this, the present embodiment 1-3 employs the graphite sheet 11 comprising the tray sheet portion 21 for covering the divided part A1 and vicinity thereof, and the boundary sheet portion 22 for covering the boundary portion A, in order to cover only the regions that are apt to be turned into SiC locally (the divided parts A1 of the graphite divided pieces 40 and the boundary portion A) by the graphite sheet 11. With such a graphite sheet 11, leakage of SiO gas can be prevented with a small amount of the sheet, and sufficient effects can be obtained for inhibiting the local SiC formation.

Although the present embodiment shows an example in which the tray portion 10 is divided into two portions, it is possible to employ a structure in which the tray portion 10 is divided into three portions, four portions, or more. In addition, although the tray sheet portion 21 and the boundary sheet portion 22 are provided integrally with each other, it is possible that they may be provided as separate parts. When they are formed integrally, misalignment can be prevented, while when they are separate parts, the processing of the sheet can be made easy.

### Other Embodiments

(1) The foregoing embodiment 1 illustrates, as an example, a carbon crucible for retaining a quartz crucible used in a silicon single crystal pulling apparatus. However, the present invention is also applicable to a carbon crucible for retaining a quartz crucible used in a metal single crystal pulling apparatus for gallium or the like.

(2) The carbon crucible may comprise a straight trunk portion 9 made of a carbon fiber-reinforced carbon composite material (C/C material) and composed of a net-shaped material woven in a net shape (for example, the net-shaped material as disclosed in Japanese Published Unexamined Patent Application Nos. H02(1990)-116696 A and 2009-203093 A).

### Embodiment 2

(Configuration of Metal Single Crystal Pulling Apparatus)

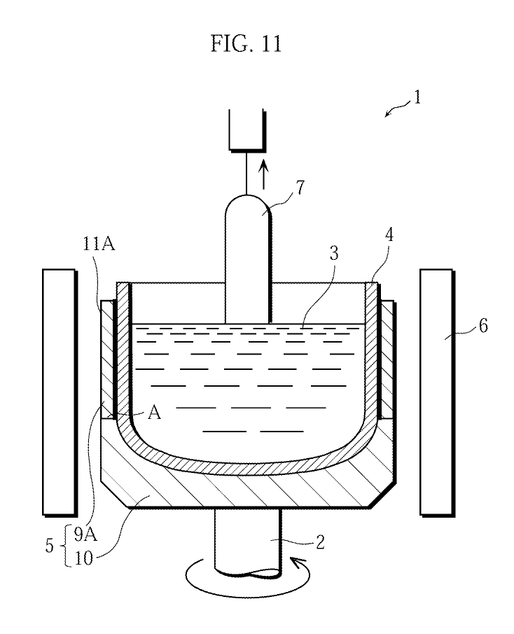

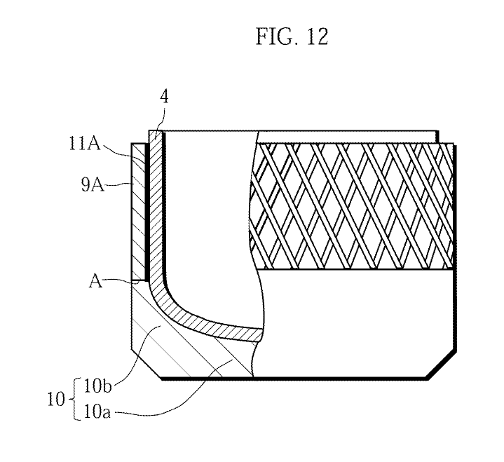

FIG. 11 is a cross-sectional view illustrating a primary portion of a silicon single crystal pulling apparatus according to Embodiment 2, and FIG. 12 is an enlarged cross-sectional view of a crucible. In FIG. 11, reference numeral 1 denotes a single crystal pulling apparatus, reference numeral 2 denotes a shaft, reference numeral 4 denotes a quartz crucible for accommodating silicon melt 3, and reference numeral 5 denotes a carbon crucible for retaining the quartz crucible 4 by retaining the outer circumferential surface of the quartz crucible 4 in such a condition as to surround it. A heater 6 is disposed around the outer periphery of the carbon crucible 5. The silicon melt 3 is heated by the heater 6 through the carbon crucible 5 and the quartz crucible 4, and while pulling up an ingot 7, a silicon single crystal is produced.

The carbon crucible 5 has a substantially circular tubular straight trunk portion 9A, a tray portion 10, and a graphite sheet 11A disposed so as to cover at least the entire inner surface of the straight trunk portion 9A. The types of the materials, arrangement embodiments, and the like of the graphite sheet 11A will be described below.

The straight trunk portion 9A is made of a carbon fiber-reinforced carbon composite material (C/C material) and composed of a net-shaped material woven in a net shape. The net-shaped material is such that strands formed by bundling a plurality of carbon fibers into a rope-like shape are disposed diagonally and woven alternately, and thereafter, pyrocarbon is impregnated therein at 10% to 150% by a CVI (chemical vapor infiltration) method, for example. It is preferable that the aperture ratio of the mesh of the net-shaped material (i.e., the ratio of the total area of the mesh to the outer surface area of the net-shaped material) be from 15% to 98%. The reason is that if the aperture ratio is less than 15%, the heat dissipating effect becomes too small. On the other hand, if the aperture ratio exceeds 98%, the mechanical strength becomes too weak, which is undesirable.

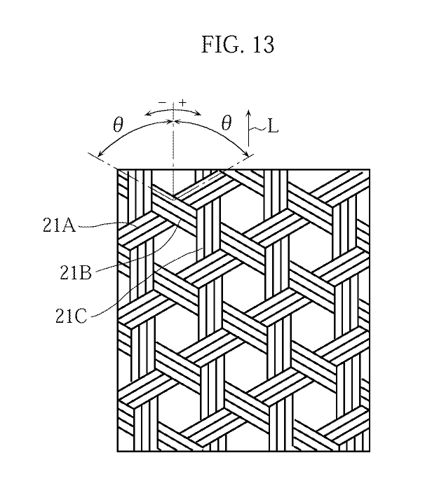

The net-shaped material may be the one as disclosed in Japanese Published Unexamined Patent Application No. 2009-203093 A. More specifically, as illustrated in FIG. 13, the net-shaped material may be formed of a triaxial woven fabric structure comprising first strands 21A inclined +θ degrees (0<θ<90) with respect to the axis line L of the net-shaped material, second strands 21B inclined −θ degrees with respect to the axis line L, and vertical strands 21C oriented substantially parallel to the axis line L.

The tray portion 10 is made of graphite. As illustrated in FIG. 12, the tray portion 10 comprises a bottom portion 10a and a curved surface-shaped portion (hereinafter referred to as the “curved portion”) 10b connected from the bottom portion 10a to the straight trunk portion 9A. It is possible that the upper edge of the tray portion 10 that is in contact with the straight trunk portion 9A may be provided with a surface level difference such that one of the inner circumferential side and the outer circumferential side is lower than the other, whereby the straight trunk portion 9A can be fitted thereto, in order to reduce the risk of detachment of the straight trunk portion 9A from the tray portion 10 and the risk of misalignment of the straight trunk portion 9A in a lateral direction.

It is preferable that the graphite sheet 11A be an expanded graphite sheet. Since the expanded graphite sheet has high cushioning capability, the quartz crucible can be retained resiliently because of the cushioning capability even when the area in the net-shaped material by which the quartz crucible is retained is small. As a result, the quartz crucible is prevented from breaking at the time of installing the quartz crucible. It is preferable that the expanded graphite sheet used as the graphite sheet 11A have a thickness of from about 0.2 mm to about 1.0 mm and a bulk density of from about 0.7 g/cm³ to about 1.3 g/cm³.

It is also preferable that the graphite sheet 11A be one with high purity that has an ash content of 100 ppm or less, more preferably ash content 50 ppm or less. The reason is that it makes possible to reduce the metallic impurities originating from the graphite sheet and lead to stabilization of the quality of, in particular, metal single crystals for semiconductor applications. In addition, the highly purified sheet has high hardness, and therefore, it can increase the effect of inhibiting the softened quartz crucible from protruding outside.

The straight trunk portion 9A and the tray portion 10 may be composed of separate parts so that the straight trunk portion 9A and the tray portion 10 can be integrated with each other by fitting them with each other. Alternatively, the straight trunk portion 9A and the tray portion 10 may be integrally formed by a net-shaped material.

(Arrangements of the Graphite Sheet)

There exist various embodiments of arrangement of the graphite sheet 11A as described below.

(1) An embodiment in which the graphite sheet 11A is disposed so as to cover the entire inner surface of the straight trunk portion 9A formed of a net-shaped material (the straight trunk portion 9A is hereinafter referred to as the “net-shaped straight trunk portion 9A”) (see FIG. 12).

When the graphite sheet 11A is disposed according to the just-described arrangement embodiment, the net-shaped straight trunk portion 9A and the quartz crucible 4 do not come into direct contact with each other, and therefore, it is less likely to cause the deterioration of the net-shaped straight trunk portion 9A resulting from the reaction with the quartz crucible 4. As a result, the net-shaped straight trunk portion 9A can be used repeatedly by replacing only the graphite sheet 11A. Moreover, easy detachment from the quartz crucible 4 and prevention of encroachment of the quartz crucible 4 into the net-shaped straight trunk portion 9A are achieved.

In addition, since the entire inner surface of the net-shaped straight trunk portion 9A is covered by the graphite sheet 11A, all the mesh holes are closed. As a result, formation of the bumps and dents in the inner surface of the quartz crucible 4, which results from protrusion of the quartz crucible 4 from the inner surface of the net-shaped straight trunk portion 9A that is caused by softening of the quartz crucible 4, is alleviated. As a result, the flow of the melt in the quartz crucible that is rotated in one direction is stabilized. Therefore, the metal single crystal obtained by pulling can be one that has less defects and stable quality. Moreover, the area of the quartz crucible 4 that is exposed inside the furnace becomes remarkably small, so it is possible to reduce the risk that the SiO gas generated from the quartz crucible 4 may cause adverse effects on the internal material of the furnace.

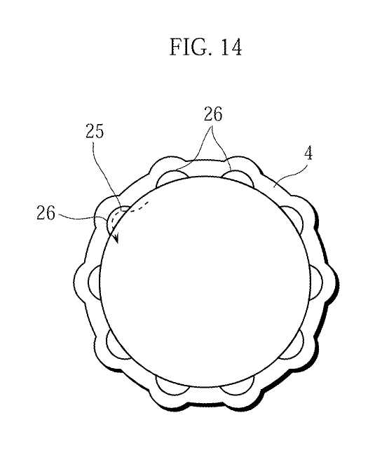

Here, the above-mentioned turbulence of the melt will be explained with reference to FIG. 14. If the graphite sheet 11A is absent, bumps and dents are formed in the inner surface of the quartz crucible 4, which result from softening of the quartz crucible 4 that is caused by protrusion of the quartz crucible 4 from the inner surface of the net-shaped straight trunk portion 9A. When the crucible is rotated in one direction under such a condition, the melt in the quartz crucible 4 flows into the dents 26, as indicated by an arrow 25, causing turbulence in the flow of the melt in the quartz crucible. What is more, the turbulence occurs three-dimensionally and locally, which hinders the crystal growth of the metal single crystal, leading to degradation of the quality. However, by disposing the graphite sheet 11A according to the present invention so as to cover the entire inner surface of the straight trunk portion 9A, formation of bumps and dents in the quartz crucible 4 is alleviated. Therefore, the flow of the melt becomes stable, and the resulting metal single crystal has few defects and stable quality.

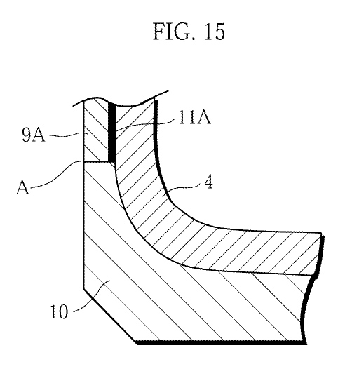

(2) An embodiment in which the graphite sheet 11A is disposed so as to unitarily cover the entire inner surface of the net-shaped straight trunk portion 9A and also the boundary portion A between the net-shaped straight trunk portion 9A and the tray portion 10 (see FIG. 15).

When the graphite sheet 11A is disposed according to the just-described arrangement embodiment, leakage of SiO gas from the gap in the boundary portion A between the tray portion 10 and the net-shaped straight trunk portion 9A can be prevented, and the local SiC formation can be inhibited. Moreover, misalignment of the net-shaped straight trunk portion 9A from the tray portion 10 can also be inhibited.

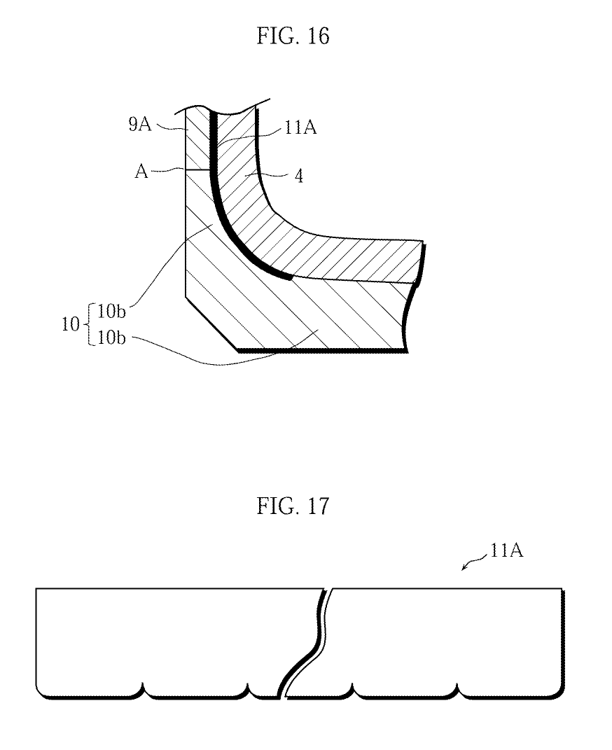

(3) An embodiment in which the graphite sheet 11A is disposed so as to unitarily cover the entire inner surface of the net-shaped straight trunk portion 9A and also the curved portion 10b of the tray portion 10 (see FIG. 16).

When the graphite sheet 11A is disposed according to the just-described arrangement embodiment, the curved portion 10b, which is consumed most among the net-shaped straight trunk portion 9A, the boundary portion A, and the tray portion 10, is unitarily covered. As a result, the local SiC formation can be inhibited.

The graphite sheet 11A may have, for example, a shape in which the upper portion thereof follows the net-shaped straight trunk portion 9 and the lower end and vicinity thereof follow the curved portion 10b of the tray portion 10, as illustrated in FIG. 17.

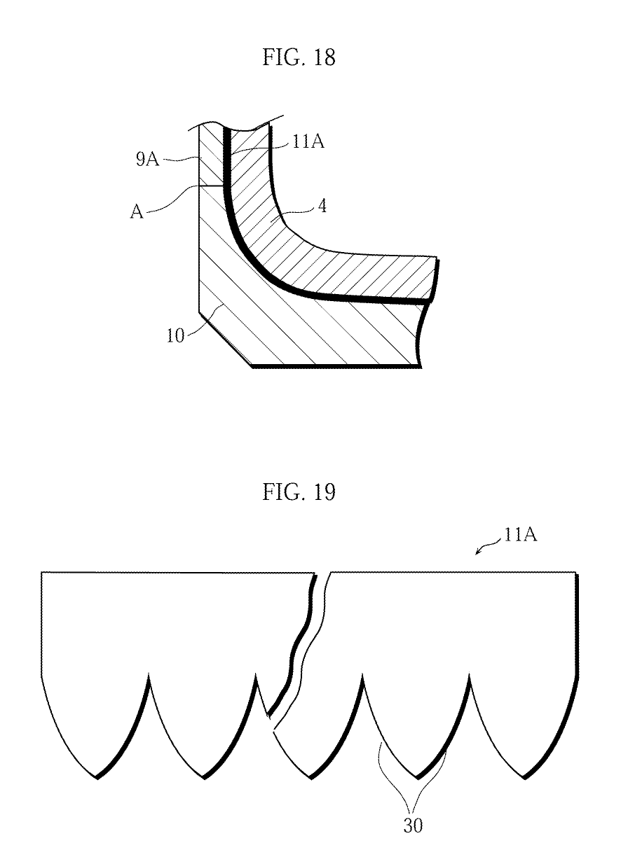

(4) An embodiment in which the graphite sheet 11A is disposed so as to unitarily cover the inner surface of the net-shaped straight trunk portion 9A and the tray portion 10 (see FIG. 18).

When the graphite sheet 11A is disposed according to the just-described arrangement embodiment, gaps caused by misalignment of the sheet are unlikely to be formed since the inner surface is covered by the one-piece sheet. As a result, SiO gas is prevented from leaking, and the net-shaped straight trunk portion 9A and the quartz crucible 4 are prevented from, for example, making contact with each other.

The graphite sheet 11A in this embodiment may be, for example, a sheet having the shape shown in FIG. 19. Specifically, by forming incisions 30 at the lower end of the sheet 11 so that the sheet can follow the bottom face shape of the crucible, the bottom portion of the sheet forms a spherical face. The size of the incision 30 can be determined as appropriate according to the shape of the crucible, particularly according to the curvature of the bottom portion.

(5) An embodiment in which the graphite sheet 11 is disposed so that a flat circular shaped sheet for covering the inner surface of the tray portion 10 and a tubular sheet for covering the inner surface of the straight trunk portion 9A are combined with each other and that both of the sheets are overlapped at the boundary portion A.

When the tray portion 10 and the net-shaped straight trunk portion 9A are made of separate parts and especially when the vertical size of the net-shaped straight trunk portion 9A is large, the sheet can be processed easily for covering the necessary portions without any gap. Moreover, since both sheets are overlapped so as to eliminate gaps therebetween, the quartz crucible 4 and the tray portion 10 are prevented from making contact with each other.

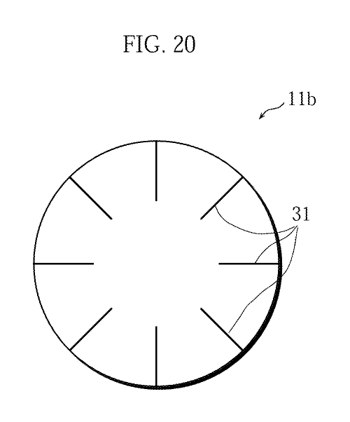

In this embodiment, the flat circular shaped sheet 11a may be, for example, a sheet having the shape shown in FIG. 20, and the tubular sheet may be, for example, a sheet having the shape shown in FIG. 17. With the sheet having the shape shown in FIG. 20, slits 31 provided in the outer periphery of the circular shape allow the peripheral region of the circular shape to be in such a shape as to follow the curved portion, and both sheets overlap with each other at a slightly downward portion of the curved portion by combining it with the sheet as shown in FIG. 17, to thus obtain an arrangement with no gap.

(Manufacturing Method of the Expanded Graphite Sheet)

The expanded the graphite sheet 11A used in this embodiment is fabricated in the same manner as the expanded the graphite sheet 11 used in the foregoing embodiment 1.

Specifically, the expanded graphite sheet may be manufactured in the following manner. A one-piece expanded graphite sheet is a sheet-like material made from expanded graphite, and a typical example is as follows. First, natural graphite, natural or synthetic graphite flakes, kish graphite, or the like are treated with an oxidizing agent, to form an intercalation compound in the graphite particles. Next, this is heated to a high temperature, or preferably exposed abruptly to a high temperature to expand the material rapidly. This treatment causes the graphite particles to expand in a direction perpendicular to the layer plane due to the gas pressure of the intercalation compound of the graphite particles, so that the volume rapidly expands from about 100 times to 250 times normally. The oxidizing agent used in this case is one that forms an intercalation compound, such as a sulfuric acid, a nitric acid, a mixed acid thereof, and a sulfuric acid to which an oxidizing agent such that a sodium nitrate, a potassium permanganate, or the like is added.

Next, impurities are removed to an ash content of 100 ppm or less, more preferably to an ash content of 50 ppm or less, and the expanded graphite is formed into a sheet shape by compressing or roll-forming, to prepare an expanded graphite sheet.

Next, the expanded graphite sheet manufactured in the just-described manner are cut and split into predetermined dimensions and shapes according to the above-described arrangement embodiments, to prepare the expanded graphite sheet 11A according to the present invention.

### Other Embodiment

Embodiment 2 above illustrates, as an example, a carbon crucible for retaining a quartz crucible used in a silicon single crystal pulling apparatus. However, the present invention is also applicable to a carbon crucible for retaining a quartz crucible used in a metal single crystal pulling apparatus for gallium or the like.

### INDUSTRIAL APPLICABILITY

The present invention is applicable to a carbon crucible for retaining a quartz crucible used in a metal single crystal pulling apparatus for silicon or the like.

### REFERENCE SIGNS LIST

1—Single crystal pulling apparatus

4—Quartz crucible

5—Carbon crucible

9, 9A—Straight trunk portion

10—Tray portion 10

10a—Bottom portion of tray portion 10

10b—Curved surface-shaped portion (curved portion) of tray portion 10

11, 11A—Graphite sheet

21—Tray sheet portion

22—Boundary sheet portion

40—Graphite divided piece

A—Boundary portion

A1—Divided portion

1. A carbon crucible having a straight trunk portion and a tray portion divided from each other, characterized in that a graphite sheet is disposed so as to cover at least a boundary portion of an inner surface of the carbon crucible between the straight trunk portion and the tray portion.

2. The carbon crucible according to claim 1, wherein the graphite sheet is an expanded graphite sheet.

3. The carbon crucible according to claim 1, wherein the graphite sheet has an ash content of 100 ppm or less.

4. The carbon crucible according to claim 1, wherein the straight trunk portion is made of a carbon fiber-reinforced carbon composite material, and the graphite sheet is disposed so as to cover an entire inner surface of the straight trunk portion in addition to the boundary portion.

5. The carbon crucible according to claim 1, wherein the straight trunk portion comprises a plurality of graphite divided pieces divided from each other, and the graphite sheet is disposed so as to cover an entire inner surface of the straight trunk portion in addition to the boundary portion.

6. The carbon crucible according to claim 1, wherein the tray portion comprises a bottom portion and a curved surface-shaped portion connected from the bottom portion to the straight trunk portion, and the graphite sheet is disposed so as to unitarily cover an entire inner surface of the straight trunk portion and the curved surface-shaped portion, in addition to the boundary portion.

7. The carbon crucible according to claim 1, wherein the graphite sheet is disposed so as to unitarily cover the inner surface of the carbon crucible.

8. The carbon crucible according to claim 7, wherein the graphite sheet comprises a flat circular shaped sheet for covering the inner surface of the tray portion and a tubular sheet for covering the inner surface of the straight trunk portion, the flat circular shaped sheet and the tubular sheet being combined with each other, and both of the sheets are overlapped at the boundary portion.

9. The carbon crucible according to claim 7, wherein: the tray portion comprises a plurality of graphite divided pieces divided from each other; and the graphite sheet comprises a tray sheet portion for covering a butt joint portion of the divided pieces and a vicinity thereof, and a boundary sheet portion for covering the boundary portion.

10. The carbon crucible according to claim 1, wherein the graphite sheet comprises a plurality of graphite sheets stacked on each other.

11. The carbon crucible according to claim 1, wherein the graphite sheet has a thickness of from 0.2 mm to 1.0 mm and a bulk density of from 0.7 g/cm³ to 1.3 g/cm³.

12. The carbon crucible according to claim 1, wherein the straight trunk portion comprises a net-shaped material made of a carbon fiber-reinforced carbon composite material and woven in a net shape, and the graphite sheet is disposed so as to cover an entire inner surface of the straight trunk portion in addition to the boundary portion.

13. The carbon crucible according to claim 12, wherein the graphite sheet is an expanded graphite sheet.

14. The carbon crucible according to claim 12, wherein the graphite sheet has an ash content of 100 ppm or less.

15. The carbon crucible according to claim 12, wherein:
the tray portion comprises a bottom portion and a curved surface-shaped portion connected from the bottom portion to the straight trunk portion; and
the graphite sheet is disposed so as to unitarily cover the entire inner surface of the straight trunk portion and the curved surface-shaped portion.

16. The carbon crucible according to claim 12, wherein the graphite sheet is disposed so as to unitarily cover the entire inner surface of the straight trunk portion and the tray portion.

17. The carbon crucible according to claim 12, wherein the graphite sheet comprises a flat circular shaped sheet covering the inner surface of the tray portion and a tubular sheet covering the inner surface of the straight trunk portion, the flat circular shaped sheet and the tubular sheet being combined with each other, and both of the sheets are overlapped at the boundary portion.

18. The carbon crucible according to claim 12, wherein the graphite sheet has a thickness of from 0.2 mm to 1.0 mm and a bulk density of from 0.7 g/cm³ to 1.3 g/cm³.
